(19) United States
(12) Patent Application Publication
(10) Pub. No.: US 2023/0299236 A1
(43) Pub. Date: Sep. 21, 2023

(54) SUBSTRATE PROCESSING FOR GaN GROWTH

(71) Applicant: Applied Materials, Inc., Santa Clara, CA (US)

(72) Inventors: Michel Khoury, Mountain View, CA (US); Ria Someshwar, Mountain View, CA (US)

(73) Assignee: Applied Materials, Inc., Santa Clara, CA (US)

(21) Appl. No.: 17/695,206

(22) Filed: Mar. 15, 2022

(51) Int. Cl. H01L 33/32; H01L 33/00

(52) U.S. Cl. CPC H01L 33/32; H01L 33/007; H01L 33/0095

(57) ABSTRACT

Exemplary semiconductor structures may include a silicon-containing substrate. The structures may include a first layer of a first metal nitride overlying the silicon-containing substrate. The structures may include a second layer of a second metal nitride overlying the first layer of the first metal nitride. The structures may include a gallium nitride structure overlying the layer of the metal nitride.

### TECHNICAL FIELD

The present technology relates to semiconductor processing and materials. More specifically, the present technology relates to formation processes and materials for light-emitting diode structures and components.

### BACKGROUND

LED panels or devices may be formed with a number of light sources that operate as pixels on the device. The pixels may be formed with monochromatic light sources that are then delivered through a conversion layer to produce color, or the pixels may each have individual color light sources formed. In either scenario, any number up to millions of light sources may be formed and connected for operation. While there have been considerable developments to light sources used in LED panels, producing the structures may still be prone to defects causing reduced performance.

Thus, there is a need for improved systems and methods that can be used to produce high quality devices and structures. These and other needs are addressed by the present technology.

### SUMMARY

Exemplary semiconductor structures may include a silicon-containing substrate. The structures may include a first layer of a first metal nitride overlying the silicon-containing substrate. The structures may include a second layer of a second metal nitride overlying the first layer of the first metal nitride. The structures may include a gallium nitride structure overlying the first layer of the first metal nitride.

In some embodiments, the silicon-containing substrate may be or include silicon. The first metal nitride and the second metal nitride may be selected from the group consisting of aluminum nitride, hafnium nitride, and niobium nitride. The first metal nitride may be or include aluminum nitride and the second metal nitride may be or include hafnium nitride. The structures may include a dielectric material layer overlying at least a portion of the second layer of the second metal nitride. The dielectric material layer may be or include silicon nitride. The dielectric material layer may be discontinuous.

Some embodiments of the present technology may encompass semiconductor processing methods. The methods may include forming a first layer of a first metal nitride material on a substrate. The methods may include forming a second layer of a second metal nitride material on the first layer of the first metal nitride. The methods may include annealing the first layer of the first metal nitride and the second layer of the second metal nitride. The methods may include forming a gallium-containing material on the second layer of the second metal nitride.

In some embodiments, the first metal nitride may be selected from the group consisting of aluminum nitride and niobium nitride. The second metal nitride may be or include hafnium nitride. The first layer of the first metal nitride and the second layer of the second metal nitride may be formed by physical vapor deposition. The first layer of the first metal nitride and the second layer of the second metal nitride may be formed at a temperature of less than or about 1,000° C. Annealing the first layer of the first metal nitride and the second layer of the second metal nitride may include an anneal at a temperature of greater than or about 800° C. A surface of the second layer of the second metal nitride opposite the first layer of the first metal nitride may be characterized by a maximum roughness of less than or about 1.0 μm. The gallium-containing material may be characterized by a pyramidal structure. The gallium-containing material may be or include gallium nitride.

Some embodiments of the present technology may encompass semiconductor processing methods. The methods may include forming a first layer of a first metal nitride material on a silicon substrate. The methods may include forming a second layer of a second metal nitride material on the first layer of the first metal nitride. The methods may include annealing the first layer of the first metal nitride and the second layer of the second metal nitride at a temperature greater than or about 800° C. The methods may include forming a dielectric material on the second layer of the second metal nitride. The dielectric material may be discontinuous. The methods may include forming a gallium-containing material on the second layer of the second metal nitride between portions of the dielectric material.

In some embodiments, the second layer of the second metal nitride may be formed at a lower temperature than the first layer of the first metal nitride. The first layer of the first metal nitride and the second layer of the second metal nitride may be formed by physical vapor deposition. The first metal nitride may be or include aluminum nitride and the second metal nitride may be or include hafnium nitride. The gallium-containing material may be or include gallium nitride.

Such technology may provide numerous benefits over conventional systems and techniques. For example, the present technology may provide methods of forming gallium-containing materials characterized by reduced dislocations or defects extending through the materials. Additionally, the present technology may afford the ability to utilize physical vapor deposition to produce seed layers for growing gallium-nitride materials. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing system according to some embodiments of the present technology.

FIG. 2 shows selected operations in a method of forming a semiconductor structure according to some embodiments of the present technology.

FIGS. 3A-3D illustrate schematic views of a device developed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

LEDs may include semiconductor structures that emit light when current flows through the structure. Electrons in the semiconductor may recombine with electron holes, releasing energy in the form of photons. Many conventional LEDs are formed with a thick film, such as thicker than a micron, that may define quantum wells. Dislocations, such as threading dislocations or defects, may propagate through the material in the quantum well, such as from the underlying substrate, and may result in non-radiative recombination in the quantum well region, where the LED emits a phonon instead of a photon. Threading dislocations in conventional technologies may readily pass through to the surface of the quantum well, which may undesirably increase the non-radiative recombination. These dislocations may form or exist due to a number of aspects related to the growth or structural formation process, and the dislocations may carry through the subsequent device layers formed, including the LED active region, which may further reduce the efficiency of the device.

Conventional technologies may utilize complex and expensive processing operations to develop the quantum well material in an attempt to reduce dislocations, and may be limited to specific materials and processes for the structure. For example, metal-oxide chemical vapor deposition may be used to form both a seed layer over a substrate, as well as the subsequent material used for the quantum well. This process may be expensive and time consuming. However, conventional technologies have been incapable of utilizing alternative techniques to produce the seed layer, and dislocation density may still be unfavorably high. For example, physical vapor deposition may produce films characterized by reduced structural or film characteristics, which may prevent adequate growth of the quantum well material. As one non-limiting example, gallium nitride may be used as the quantum well material in some devices, and conventional technologies have been unable to grow this material on metal nitride seed layers produced by physical vapor deposition, which may be characterized by more poorly oriented crystal structures. Because of the structure of the metal nitride produced, the polar gallium nitride material may form crystals characterized by mixed polarity, with regions of gallium-polar growth and regions of nitrogen-polar growth. This may prevent the structure from appropriately coalescing to form a quantum well, and the device may fail.

The present technology may overcome issues associated with conventional technologies, and may cure or otherwise overcome the previous limitations of physical vapor deposition nitride materials. By forming seed layers having two metal nitride layers according to embodiments of the present technology using physical vapor deposition, improved throughput and improved growth of gallium-containing materials may be facilitated. Accordingly, dislocations or defects may be controlled or minimized, which may improve device quality and performance. Although the remaining disclosure will routinely identify specific LED materials and processes utilizing the disclosed technology, it will be readily understood that the systems and methods are equally applicable to a variety of materials and processes as may occur for producing displays. Accordingly, the technology should not be considered to be so limited as for use with LED processes alone. After discussing an exemplary chamber system that may be used according to some embodiments of the present technology, methods for producing high-quality structures will be described.

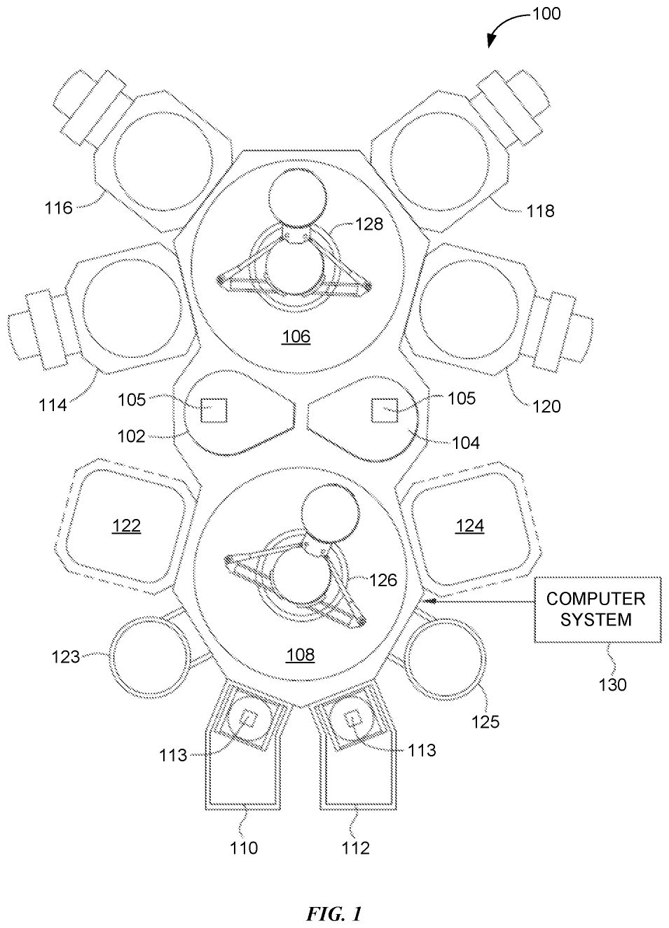

FIG. 1 illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108, and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

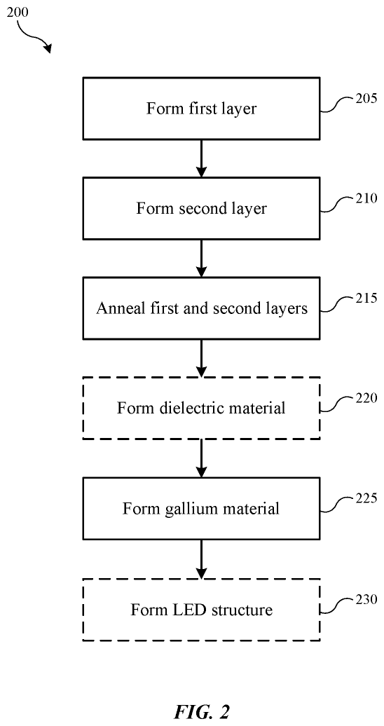

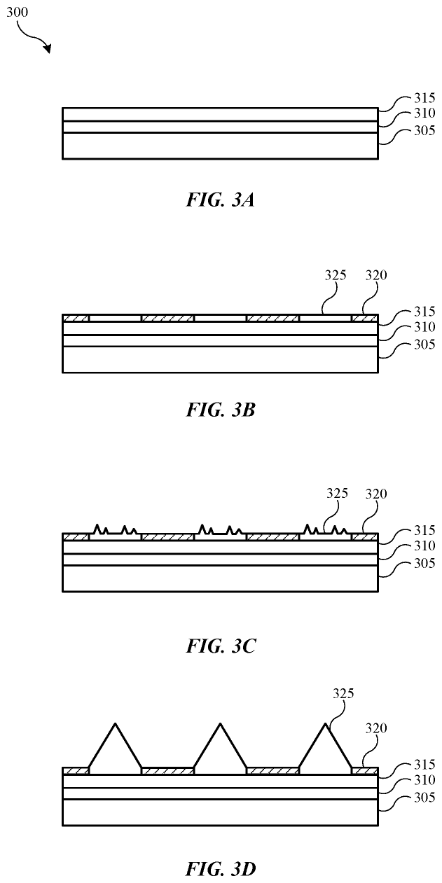

FIG. 2 illustrates selected operations of a semiconductor processing method 200. Method 200 may include one or more operations prior to the initiation of the method, including front end processing, deposition, etching, polishing, cleaning, or any other operations that may be performed prior to the described operations. For example, in some embodiments a degas or other preparatory operation may be performed on a substrate, such as silicon or sapphire substrate, to prepare the substrate for deposition. The method may include a number of optional operations, which may or may not be specifically associated with some embodiments of methods according to the present technology. For example, many of the operations are described in order to provide a broader scope of the structural formation, but are not critical to the technology, or may be performed by alternative methodology as will be discussed further below. Method 200 describes operations shown schematically in FIGS. 3A-3D, the illustrations of which will be described in conjunction with the operations of method 200. It is to be understood that the figures illustrate only partial schematic views, and a substrate may contain any number of sections having aspects as illustrated in the figures, as well as alternative structural aspects that may still benefit from aspects of the present technology.

Method 200 may involve optional operations to develop the structure to a particular fabrication operation. As illustrated in FIG. 3A, a semiconductor structure 300 may include a substrate 305 that may be used to facilitate formation of a number of structures utilized in LED formation or other semiconductor processing. Substrate 305 may be any substrate on which structures may be formed, such as silicon-containing materials, aluminum materials, including sapphire, or any other materials as may be used in display or semiconductor fabrication. The substrate 305 may have various dimensions, such as 200 mm or 300 mm diameter wafers, as well as rectangular or square panels. The substrate 305 may be cleaned or processed in preparation for depositing one or more layers of material on the substrate for producing a structure, such as an LED, for example, although any number of other semiconductor structures may similarly benefit from aspects of the present technology.

A first layer of a first metal nitride 310 may be formed overlying the substrate 305 at operation 205. A second layer of a second metal nitride 315 may be formed overlying the first layer of the first metal nitride 310 at operation 210. Together, the first layer of the first metal nitride 310 and the second layer of the second metal nitride 315 may form a nitrogen-containing nucleation or seed layer. The first metal nitride and the second metal nitride may be or include different metal nitrides. In some embodiments, each of the first layer and the second layer of the nucleation or seed layer may include aluminum nitride, hafnium nitride, niobium nitride, gallium nitride, or any other metal nitride on which gallium-containing materials or other materials may be formed. In one exemplary embodiment, the first metal nitride may include aluminum nitride and the second metal nitride may include hafnium nitride. In such an embodiment, if the first metal nitride includes hafnium nitride, the hafnium nitride may interact with a silicon substrate to form silicides, which may inhibit growth of subsequent material, such as gallium nitride, thereby affecting final device performance. Accordingly, the present technology may avoid interaction between the certain metal nitrides, such as hafnium nitride, and the substrate by providing an intermediate metal nitride, such as aluminum nitride, between the substrate and the second metal nitride. This configuration may permit increased throughput and reduce queue times, while simultaneously allowing for ideal material growth on the seed layer

The first layer of the first metal nitride 310 and the second layer of the second metal nitride 315 may be formed in any number of ways, such as by metal-oxide chemical vapor deposition, although in some embodiments, the seed layer may be formed by physical vapor deposition. It is contemplated that the layers may be formed using the same or different deposition or growth methods. The first layer of the first metal nitride 310 and the second layer of the second metal nitride 315 may be formed at a temperature of less than or about 1,000° C., and may be formed at a temperature of less than or about 950° C., less than or about 900° C., less than or about 850° C., less than or about 800° C., less than or about 750° C., or less. In embodiments, the second layer of the second metal nitride 315 may be formed at a lower temperature than the first layer of the first metal nitride 310. However, it is contemplated that the two layers may be formed at the same temperature or that the second layer of the second metal nitride 315 may be formed at a higher temperature than the first layer of the first metal nitride 310.

As noted above, conventional technologies have been incapable of utilizing physical vapor deposition for seed layer formation because the produced material is typically characterized by disorientation of the structure. Physical vapor deposition formation of the seed layer may provide unfavorable kinetics for gallium nitride growth, which may lead to any number of issues. The interface produced between the seed layer and subsequently formed gallium materials facilitates greater transmission of defects, as well as production of mixed polarity gallium nitride, which may detrimentally reduce efficiency and quality of the quantum well. Accordingly, conventional technologies have been constrained to utilizing more expensive technologies, such as e-beam or metal-oxide chemical vapor deposition. Furthermore, the present technology may allow for higher throughput and lower temperatures when forming the seed layer. Conventional technologies require forming thick buffer layers with slow formation times. Metal nitride seed bilayers of the present technology formed using physical vapor deposition at lower temperatures than conventional technologies may obviate the need for thick buffer layers to grow gallium-containing materials.

Method 200 may include annealing the seed layer at operation 220. The anneal may be performed at high temperatures, which may improve the crystalline structure of the seed layer, including at an exposed surface, and which may help to reduce or limit transmission of dislocations through the subsequently formed layers, and may facilitate improved growth of gallium materials. The anneal may be performed at a temperature of greater than or about 800° C., and may be performed at a temperature of greater than or about 850, greater than or about 900° C., greater than or about 950° C., greater than or about 1,000° C., greater than or about 1,150° C., greater than or about 1,200° C., greater than or about 1,250° C., greater than or about 1,300° C., greater than or about 1,350° C., greater than or about 1,400° C., greater than or about 1,450° C., greater than or about 1,500° C., greater than or about 1,550° C., greater than or about 1,600° C., or higher. However, depending on the substrate material, a lower temperature may be used, which may facilitate treatment of the seed layer, but may protect the substrate. For example, in some embodiments, the substrate may be silicon, which may be damaged or melt at higher temperatures. Accordingly, in some embodiments, and depending on the substrate, the temperature may be maintained at less than or about 1,500° C., and may be maintained at less than or about 1,400° C., less than or about 1,300° C., or less.

The anneal may be performed for a period of time sufficient to improve the seed layer, and the anneal may be performed for greater than or about 30 minutes, greater than or about 60 minutes, greater than or about 90 minutes, greater than or about 120 minutes, greater than or about 150 minutes, greater than or about 180 minutes, or more. The time period may be related to the anneal temperature, where a higher temperature anneal may be performed for a reduced period of time, while producing similar effects. For example, while an anneal at greater than or about 1,600° C. may be performed for a time period of less than or about 30 minutes, an anneal performed at a temperature of less than or about 1,200° C. may be performed for greater than or about 90 minutes. The anneal may be performed in any processing atmosphere, but in some embodiments the anneal may be performed in an inert atmosphere, such as a nitrogen atmosphere, an argon atmosphere, a helium atmosphere, among other non-reactive, oxygen-deprived, or other inert materials.

Subsequent the anneal operation, a surface of the second layer of the second metal nitride 315 opposite the first layer of the first metal nitride 310 may be characterized by a maximum roughness of less than or about 1.0 μm. An increase in roughness may indicate a change in qualities of the seed layer during the anneal, such as a change in the crystalline structure from monocrystalline to polycrystalline, which may affect subsequent gallium growth on the seed layer. The present technology may maintain a maximum roughness of less than or about 1.0 μm due, in part, to the seed layer including a first metal nitride and a second metal nitride overlying the first metal nitride. The presence of two metal nitrides may reduce or eliminate any silicidation occurring during the anneal operation. In embodiments, the surface of the second layer of the second metal nitride 315 opposite the first layer of the first metal nitride 310 may be characterized by a maximum roughness of less than or about 950 nm, and may be characterized by a maximum roughness of less than or about 900 nm, less than or about 850 nm, less than or about 800 nm, less than or about 750 nm, less than or about 700 nm, less than or about 650 nm, less than or about 600 nm, less than or about 550 nm, less than or about 500 nm, less than or about 450 nm, less than or about 400 nm, less than or about 350 nm, less than or about 300 nm, less than or about 250 nm, less than or about 200 nm, less than or about 150 nm, less than or about 100 nm, less than or about 50 nm, or less.

A dielectric material 320 may be formed on the second layer of the second metal nitride at operation 220. The dielectric material 320 may be or include any dielectric material such as, but not limited to, silicon nitride, silicon oxide, aluminum nitride, aluminum oxide, or boron nitride. As shown in FIG. 3B, the dielectric material 320 may be formed and patterned across the second layer of the second metal nitride 315 such that the dielectric material 320 is discontinuous or that gaps or windows are produced between the dielectric material 320, exposing portions of the underlying second layer of the second metal nitride 315. These gaps or windows may be formed by patterning the dielectric material 320 to expose one or more regions of the second layer of the second metal nitride 315. Although only two gaps or windows are illustrated, it is to be understood that a substrate may have hundreds, thousands, millions, or more gaps or windows, and which may be of any size.

A gallium-containing material 325 may be grown at operation 225. The gallium-containing material 325, which may include gallium nitride, for example, may be grown by metal-oxide chemical vapor deposition, or by any other deposition or formation process. The gallium-containing material 325 may selectively grow on the second layer of the second metal nitride 315 of the seed layer. The gallium-containing material 325 and the dielectric material 320 may overlap slightly, but the two portions may also be distinct from one another. For example, gallium-containing material 325 may be epitaxially grown extending from the exposed seed layer, which may allow selective formation in the open regions of the dielectric material 320, while limiting or preventing growth on the dielectric material 320.

As illustrated in FIG. 3C, the gallium-containing material 325 may be characterized by discrete regions of a pyramidal shaped structures as the material grows. With further growth, the gallium-containing material 325 may coalesce and form a single pyramidal shaped structure as illustrated in FIG. 3D. However, it is contemplated that the process may facilitate growth of any structure including a continuous layer of gallium-containing material. The pyramidal shaped structures illustrated in FIG. 3D may be further processed to form LED structures.

After forming the gallium-containing material 325, method 200 may further include forming an LED structure at optional operation 230, such as in embodiments in which the gallium-nitride material may be used as a quantum well for an LED structure. Embodiments of forming an LED structure may include forming a p-doped layer over the gallium-containing material 325. The p-doped layer may be made from one or more of gallium nitride, aluminum-indium-gallium-nitride, indium-gallium-nitride, and aluminum-gallium nitride. In some embodiments, the p-doped layer may include gallium-free, indium-and-nitride materials such as indium nitride, and aluminum-indium-nitride, among other gallium-free nitride materials. Forming the LED structure may additionally include forming contact pads on the layers of the structure. The contact pads may be formed of one or more electrically conductive materials such as copper, aluminum, tungsten, chromium, nickel, silver, gold, platinum, palladium, titanium, tin, and/or indium, among other conductive materials. Any additional or alternative operations or processes for forming an LED structure may be included, as one of skill would appreciate.

The LED formation may also include forming a light conversion region on the LED structure. The light conversion region may absorb the light emitted by the LED structure and emit light at a longer wavelength from an LED display. In some embodiments, the light conversion region may be a quantum-dot layer, which may be operable to convert a shorter wavelength of light from the LED structure into one of red, green, or blue light. Additional quantum-dot layers may be formed on other LED structures to convert the shorter wavelength of light emitted by the LED structure into another of the red, green, and blue colored light. In some embodiments, combinations of three quantum-dot layers on three LED structures may form an LED pixel that includes subpixels operable to emit red, green, and blue light. In some embodiments, sequential operations may form a red quantum dot layer in one of the subpixels of each LED pixel, a green quantum dot layer in another one of the subpixels, and a blue quantum dot layer in still another one of the subpixels. Following the formation of the blue quantum dot, each LED pixel in the array of LED pixels may include red, green, and blue subpixels.

Embodiments of the present technology include operations and structures that reduce or limit the amount of threading dislocations extending through the quantum well, which may otherwise reduce efficiency and performance of the resulting structure. By forming seed layers as described above, the present technology may increase throughput and allow improved gallium-containing material growth, which may limit the prevalence and extension of dislocations through the materials. Accordingly, embodiments of the present technology may provide fabrication methods and resulting structures characterized by reduced amounts of threading dislocation for the improved efficiency of light-emitting diodes or other semiconductor structures.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either limit of the range, both limits of the range, or neither limit of the range are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a layer” includes a plurality of such layers, and reference to “the structure” includes reference to one or more structures and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor structure comprising:
a silicon-containing substrate;
a first layer of a first metal nitride overlying the silicon-containing substrate;
a second layer of a second metal nitride overlying the first layer of the first metal nitride; and
a gallium nitride structure overlying the second layer of the second metal nitride.

2. The semiconductor structure of claim 1, wherein the silicon-containing substrate is silicon.

3. The semiconductor structure of claim 1, wherein the first metal nitride and the second metal nitride are selected from the group consisting of aluminum nitride, hafnium nitride, and niobium nitride.

4. The semiconductor structure of claim 1, wherein the first metal nitride comprises aluminum nitride and the second metal nitride comprises hafnium nitride.

5. The semiconductor structure of claim 1, further comprising a dielectric material layer overlying at least a portion of the second layer of the second metal nitride.

6. The semiconductor structure of claim 5, wherein the dielectric material layer comprises silicon nitride.

7. The semiconductor structure of claim 5, wherein the dielectric material layer is discontinuous.

8. A method of semiconductor processing comprising:
forming a first layer of a first metal nitride material on a substrate;
forming a second layer of a second metal nitride material on the first layer of the first metal nitride;
annealing the first layer of the first metal nitride and the second layer of the second metal nitride; and
forming a gallium-containing material on the second layer of the second metal nitride.

9. The method of semiconductor processing of claim 8, wherein the first metal nitride is selected from the group consisting of aluminum nitride and niobium nitride, and wherein the second metal nitride comprises hafnium nitride.

10. The method of semiconductor processing of claim 8, wherein the first layer of the first metal nitride and the second layer of the second metal nitride are formed by physical vapor deposition.

11. The method of semiconductor processing of claim 8, wherein the first layer of the first metal nitride and the second layer of the second metal nitride are formed at a temperature of less than or about 1,000° C.

12. The method of semiconductor processing of claim 8, wherein annealing the first layer of the first metal nitride and the second layer of the second metal nitride comprises an anneal at a temperature of greater than or about 800° C.

13. The method of semiconductor processing of claim 12, wherein a surface of the second layer of the second metal nitride opposite the first layer of the first metal nitride is characterized by a maximum roughness of less than or about 1.0 μm.

14. The method of semiconductor processing of claim 8, wherein the gallium-containing material is characterized by a pyramidal structure.

15. The method of semiconductor processing of claim 8, wherein the gallium-containing material comprises gallium nitride.

16. A method of semiconductor processing comprising:
forming a first layer of a first metal nitride material on a silicon substrate;
forming a second layer of a second metal nitride material on the first layer of the first metal nitride;
annealing the first layer of the first metal nitride and the second layer of the second metal nitride at a temperature greater than or about 800° C.;
forming a dielectric material on the second layer of the second metal nitride, wherein the dielectric material is discontinuous; and
forming a gallium-containing material on the second layer of the second metal nitride between portions of the dielectric material.

17. The method of semiconductor processing of claim 16, wherein the second layer of the second metal nitride is formed at a lower temperature than the first layer of the first metal nitride.

18. The method of semiconductor processing of claim 16, wherein the first layer of the first metal nitride and the second layer of the second metal nitride are formed by physical vapor deposition.

19. The method of semiconductor processing of claim 16, wherein the first metal nitride comprises aluminum nitride and the second metal nitride comprises hafnium nitride.

20. The method of semiconductor processing of claim 16, wherein the gallium-containing material is gallium nitride.
